(19) United States
(12) Patent Application Publication
(10) Pub. No.: US 2025/0338602 A1
(43) Pub. Date: Oct. 30, 2025

(54) SEMICONDUCTOR DEVICE

(71) Applicant: DENSO CORPORATION, Kariya-city (JP)

(72) Inventor: Hiroki SAKANE, Kariya-city (JP)

(21) Appl. No.: 19/261,552

(22) Filed: Jul. 7, 2025

Related U.S. Application Data
(63) Continuation of application No. PCT/JP2023/037735, filed on Oct. 18, 2023.

(30) Foreign Application Priority Data
Jan. 10, 2023 (JP) 2023-001704

(51) Int. Cl. H10D 84/00; H10D 84/01

(52) U.S. Cl. CPC H10D 84/161; H10D 84/0109

(57) ABSTRACT

A semiconductor device has a gate electrode in a trench. The semiconductor substrate has: a first n-type region in contact with the gate insulating film; a p-type upper body region in contact with the gate insulating film below the first n-type region; an n-type barrier region in contact with the gate insulating film below the upper body region; a p-type lower body region in contact with the gate insulating film below the barrier region; a connection portion electrically connecting the barrier region and the upper electrode; an n-type drift region in contact with the gate insulating film below the lower body region; and a second n-type region in contact with the lower electrode. A lower portion of the gate insulating film is thicker than an upper portion of the gate insulating film.

### CROSS REFERENCE TO RELATED APPLICATIONS

The present application is a continuation application of International Patent Application No. PCT/JP2023/037735 filed on Oct. 18, 2023, which designated the U.S. and claims the benefit of priority from Japanese Patent Application No. 2023-001704 filed on Jan. 10, 2023. The entire disclosures of all of the above applications are incorporated herein by reference.

### TECHNICAL FIELD

The present disclosure relates to a semiconductor device.

### BACKGROUND

A semiconductor device includes an insulated gate bipolar transistor (IGBT) and a diode. An n-type drift region is distributed across the IGBT region and the diode region. In the IGBT region, a p-type body region is provided above the drift region. The body region is separated into an upper body region and a lower body region by an n-type barrier region. The barrier region is electrically connected to the upper electrode by a connection portion.

### SUMMARY

According to an aspect of the present disclosure, a semiconductor device includes a semiconductor substrate, a gate insulating film, a gate electrode, an upper electrode, and a lower electrode. A trench is provided in the upper surface of the semiconductor substrate. The gate insulating film covers an inner surface of the trench. The gate electrode is disposed in the trench and insulated from the semiconductor substrate by the gate insulating film. The upper electrode is in contact with the upper surface of the semiconductor substrate. The lower electrode is in contact with the lower surface of the semiconductor substrate. The semiconductor substrate has a first n-type region, an upper body region, a barrier region, a lower body region, a connection portion, a drift region, and a second n-type region. The first n-type region is in contact with the upper electrode, and is in contact with the gate insulating film at a side surface of the trench. The upper body region is a p-type region in contact with the gate insulating film at the side surface below the first n-type region. The barrier region is an n-type region in contact with the gate insulating film at the side surface below the upper body region. The lower body region is a p-type region in contact with the gate insulating film at the side surface below the barrier region and is separated from the upper body region by the barrier region. The connection portion electrically connects the barrier region and the upper electrode. The drift region is an n-type region in contact with the gate insulating film at the side surface below the lower body region. The second n-type region has a higher n-type impurity concentration than the drift region. The second n-type region is disposed below the drift region, and is in contact with the lower electrode. A lower portion of the gate insulating film within a range in contact with the lower body region is thicker than an upper portion of the gate insulating film within a range in contact with the upper body region.

### BRIEF DESCRIPTION OF DRAWINGS

FIG. 1 is a cross-sectional view of a semiconductor device according to an embodiment.

FIG. 2 is an enlarged cross-sectional view of a trench in the semiconductor device according to the embodiment.

FIG. 3 is an enlarged cross-sectional view of a trench in a semiconductor device of a comparative example.

FIG. 4 is a graph showing rising characteristics of current in a semiconductor device of a comparative example.

FIG. 5 is a graph showing rising characteristics of current for normal and abnormal IGBTs not having a barrier region and a connection portion.

FIG. 6 is an explanatory diagram illustrating a method for forming a gate insulating film.

FIG. 7 is an enlarged cross-sectional view of a trench in a semiconductor device according to a first modification.

FIG. 8 is a cross-sectional view of a semiconductor device according to a second modification.

FIG. 9 is a cross-sectional view of a semiconductor device according to a third modification.

### DESCRIPTION OF EMBODIMENTS

A semiconductor device includes an insulated gate bipolar transistor (IGBT) and a diode. An n-type drift region is distributed across the IGBT region and the diode region. In the IGBT region, a p-type body region is provided above the drift region. The body region is separated into an upper body region and a lower body region by an n-type barrier region. The barrier region is electrically connected to the upper electrode by a connection portion (more specifically, an n-type contact region). In the diode region, a p-type anode region is provided above the drift region, and an n-type cathode region is provided below the drift region. The anode region is in contact with the upper electrode, and the cathode region is in contact with the lower electrode. When the diode is turned on, holes flow from the anode region through the drift region to the cathode region. At this time, holes also flow from the body region in the IGBT region to the cathode region via the drift. When holes are injected from the body region to the cathode region in this manner, losses are likely to occur when the diode subsequently performs reverse recovery operation. In the semiconductor device, the barrier region and the connection portion are provided to suppress the flow of holes from the body region to the drift in the IGBT region, when the diode is on, so as to reduce the reverse recovery loss. The barrier region and the connection portion are provided in the semiconductor device having the IGBT and the diode, but the barrier region and the connection portion can also be provided in a metal-oxide-semiconductor field effect transistor (MOSFET). By providing a barrier region and a connection portion in a MOSFET, loss can be suppressed during a reverse recovery operation of the body diode of the MOSFET.

In a switching element having a barrier region and a connection portion, when the gate potential is increased, a minute leakage current may occur even though the gate potential has not yet reached the gate threshold value. This specification proposes a semiconductor device for suppressing the leakage current when the gate potential is increased.

According to an aspect of the present disclosure, a semiconductor device includes a semiconductor substrate, a gate insulating film, a gate electrode, an upper electrode, and a lower electrode. A trench is provided in the upper surface of the semiconductor substrate. The gate insulating film covers an inner surface of the trench. The gate electrode is disposed in the trench and insulated from the semiconductor substrate by the gate insulating film. The upper electrode is in contact with the upper surface of the semiconductor substrate. The lower electrode is in contact with the lower surface of the semiconductor substrate. The semiconductor substrate has a first n-type region, an upper body region, a barrier region, a lower body region, a connection portion, a drift region, and a second n-type region. The first n-type region is in contact with the upper electrode, and is in contact with the gate insulating film at a side surface of the trench. The upper body region is a p-type region in contact with the gate insulating film at the side surface below the first n-type region. The barrier region is an n-type region in contact with the gate insulating film at the side surface below the upper body region. The lower body region is a p-type region in contact with the gate insulating film at the side surface below the barrier region and is separated from the upper body region by the barrier region. The connection portion electrically connects the barrier region and the upper electrode. The drift region is an n-type region in contact with the gate insulating film at the side surface below the lower body region. The second n-type region has a higher n-type impurity concentration than the drift region. The second n-type region is disposed below the drift region, and is in contact with the lower electrode. A lower portion of the gate insulating film within a range in contact with the lower body region is thicker than an upper portion of the gate insulating film within a range in contact with the upper body region.

The semiconductor device may include an IGBT and a diode, or may be a MOSFET. In a semiconductor device including an IGBT and a diode, the first n-type region is an emitter region of the IGBT, and the second n-type region is a cathode region of the diode. In a MOSFET, the first n-type region is a source region and the second n-type region is a drain region. The connection portion may be an n-type connection region extending from the barrier region to the upper electrode, or may be a conductive member extending from the barrier region to the upper electrode.

As described above, in a switching element having a barrier region and a connection portion, leakage current occurs when the gate potential is increased. The leakage current flows through a channel formed in the lower body region and the connection portion. In contrast, in the semiconductor device disclosed in this specification, the lower portion of the gate insulating film within the range in contact with the lower body region is thicker than the upper portion of the gate insulating film within the range in contact with the upper body region. With this configuration, a channel is more easily formed in the upper body region than in the lower body region. Therefore, when a channel is formed in the lower body region, a current easily flows through the channel in the upper body region and the channel in the lower body region, and leakage current flowing through the connection portion and the channel in the lower body region can be suppressed.

The gate insulating film may have a thickness shift portion where the thickness increases from the upper portion toward the lower portion. In this case, the thickness shift portion may be disposed within a range in contact with the barrier region.

If the thickness shift portion exists within the range of the upper body region or the lower body region, the variation in gate threshold value becomes large during mass production of the semiconductor devices. As described above, when the thickness shift portion is disposed within a range in contact with the barrier region, the variation in the gate threshold value can be suppressed.

In the semiconductor device, as an example, a p-type impurity concentration of the lower body region may be lower than that of the upper body region.

In order to suppress electric field concentration around the trench when the semiconductor device is in an off state, the p-type impurity concentration of the lower body region can be made lower than that of the upper body region. In this case, a channel is likely to be formed in the lower body region, and the leakage current is likely to occur more significantly. Even in this case, the leakage current can be suppressed by making the lower portion of the gate insulating film thicker than the upper portion.

In the semiconductor device, the semiconductor substrate may have a p-type collector region disposed below the drift region and in contact with the lower electrode.

In the semiconductor device, the connection portion may be made of an n-type semiconductor and may be in Schottky contact with the upper electrode.

Accordingly, the leakage current can be further suppressed by the Schottky barrier.

The Schottky barrier between the connection portion and the upper electrode may be 0.7 eV or less.

In the semiconductor device, the upper portion may be made of a material different from the lower portion.

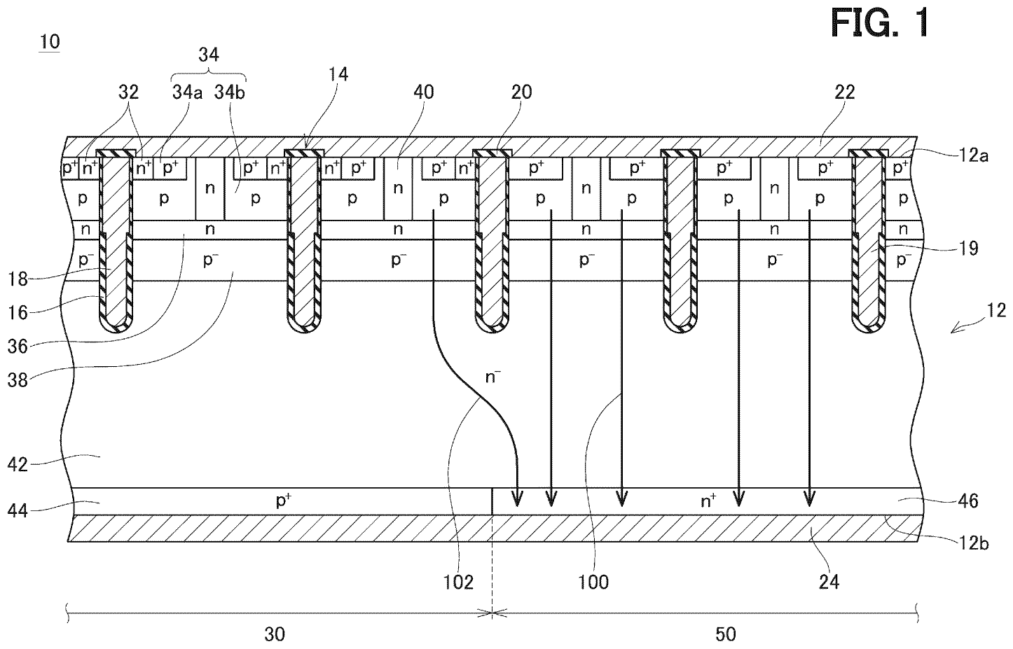

As shown in FIG. 1, a semiconductor device 10 according to an embodiment has a semiconductor substrate 12 made of silicon. The semiconductor substrate 12 may be made of other semiconductor material (for example, SiC, GaN, or the like). When viewed from the upper side, the semiconductor substrate 12 has an IGBT region 30 and a diode region 50. An IGBT is provided in the IGBT region 30, and a diode is provided in the diode region 50. The IGBT region 30 and the diode region 50 are adjacent to each other. Multiple trenches 14 are provided from the upper surface 12a of the semiconductor substrate 12. The trenches 14 extend linearly and parallel to each other on the upper surface 12a. The trenches 14 are spaced apart from one another. The trenches 14 are provided in each of the IGBT region 30 and the diode region 50. An inner surface of each of the trenches 14 is covered with a gate insulating film 16. The gate insulating film 16 is made of silicon oxide. A gate electrode 18 is disposed in each trench 14 within the IGBT region 30. The gate electrode 18 is insulated from the semiconductor substrate 12 by the gate insulating film 16. An electrode 19 is disposed in each trench 14 within the diode region 50. The electrode 19 may be connected to the gate electrode 18, or may be a dummy electrode having a potential independent of the gate electrode 18. The electrode 19 is insulated from the semiconductor substrate 12 by the gate insulating film 16. The upper surfaces of the gate electrode 18 and the electrode 19 are covered with an interlayer insulating film 20. An upper electrode 22 is disposed on the semiconductor substrate 12. The upper electrode 22 is in contact with the upper surface 12a of the semiconductor substrate 12 in the IGBT region 30 and in the diode region 50. The upper electrode 22 is insulated from the gate electrode 18 and the electrode 19 by the interlayer insulating film 20. A lower electrode 24 is disposed below the semiconductor substrate 12. The lower electrode 24 is in contact with the lower surface 12b of the semiconductor substrate 12 in the IGBT region 30 and in the diode region 50.

The semiconductor substrate 12 has plural emitter regions 32, an upper body region 34, a barrier region 36, a lower body region 38, plural connection regions 40, a drift region 42, a collector region 44, and a cathode region 46.

The emitter regions 32 are n-type regions arranged in the IGBT region 30. Each emitter region 32 is disposed within a range between two trenches 14 (hereinafter referred to as an inter-trench area). Each emitter region 32 is disposed at a position including the upper surface 12a of the semiconductor substrate 12, and is in ohmic contact with the upper electrode 22. Each emitter region 32 is in contact with the gate insulating film 16 at the upper end of the side surface of the trench 14. In FIG. 1, the emitter region 32 is arranged in the IGBT region 30 while the emitter region 32 is not arranged in the diode region 50, but the emitter region 32 may be arranged in both the IGBT region 30 and the diode region 50.

The upper body region 34 is a p-type region and is distributed across the IGBT region 30 and the diode region 50. The upper body region 34 has contact regions 34a and low concentration regions 34b. The low concentration region 34b has a lower p-type impurity concentration than the contact region 34a. Each contact region 34a is disposed within the inter-trench area. Each contact region 34a is disposed at a position including the upper surface 12a of the semiconductor substrate 12, and is in ohmic contact with the upper electrode 22. The low concentration region 34b is disposed in the inter-trench area. The low concentration region 34b is in contact with the contact region 34a from the lower side. The low concentration region 34b is electrically connected to the upper electrode 22 via the contact region 34a. In the IGBT region 30, the low concentration region 34b is in contact with the emitter region 32 from the lower side. The low concentration region 34b is in contact with the gate insulating film 16 at the side surface of each trench 14. In the IGBT region 30, the low concentration region 34b is in contact with the gate insulating film 16 below the emitter region 32.

The barrier region 36 is an n-type region distributed across the IGBT region 30 and the diode region 50. The barrier region 36 is disposed within the inter-trench area. The barrier region 36 is disposed below the low concentration region 34b. The barrier region 36 is in contact with the gate insulating film 16 at the side surface of each trench 14. The barrier region 36 is in contact with the gate insulating film 16 below the low concentration region 34b.

The lower body region 38 is a p-type region distributed across the IGBT region 30 and the diode region 50. The lower body region 38 is disposed within the inter-trench area. The lower body region 38 is disposed below the barrier region 36 and is separated from the upper body region 34 by the barrier region 36. The lower body region 38 is in contact with the gate insulating film 16 at the side surface of each trench 14. The lower body region 38 is in contact with the gate insulating film 16 below the barrier region 36. The lower body region 38 has a lower p-type impurity concentration than the low concentration region 34b of the upper body region 34.

The connection regions 40 are n-type regions. The plural connection regions 40 are arranged in each of the IGBT region 30 and the diode region 50. Each connection region 40 is disposed within the inter-trench area. Each connection region 40 extends from the barrier region 36 through the upper body region 34 to the upper electrode 22. Each connection region 40 is in Schottky contact with the upper electrode 22. The Schottky barrier at the interface between the connection region 40 and the upper electrode 22 is 0.7 eV or less.

The drift region 42 is an n-type region having a lower n-type impurity concentration than the emitter region 32. The drift region 42 is distributed across the IGBT region 30 and the diode region 50. The drift region 42 is located to overlap the lower portion of the trench 14. The upper end of the drift region 42 is located within the inter-trench area. The drift region 42 is in contact with the lower body region 38 from the lower side within each inter-trench area. The drift region 42 is in contact with the gate insulating film 16 at the side surface and the bottom surface of each trench 14. The drift region 42 is in contact with the gate insulating film 16 below the lower body region 38.

The collector region 44 is a p-type region disposed within the IGBT region 30. The collector region 44 is in contact with the drift region 42 from the lower side. The collector region 44 is in ohmic contact with the lower electrode 24.

The cathode region 46 is an n-type region having a higher n-type impurity concentration than the drift region 42. The cathode region 46 is disposed within the diode region 50. The cathode region 46 is in contact with the drift region 42 from the lower side. The cathode region 46 is in ohmic contact with the lower electrode 24.

In the diode region 50, the upper body region 34 and the lower body region 38 function as a p-type anode region. In the diode region 50, a PIN diode is formed by the upper body region 34, the lower body region 38, the drift region 42 and the cathode region 46. In the IGBT region 30, an IGBT is formed by the emitter region 32, the upper body region 34, the lower body region 38, the drift region 42, the collector region 44, the gate electrode 18 and the gate insulating film 16.

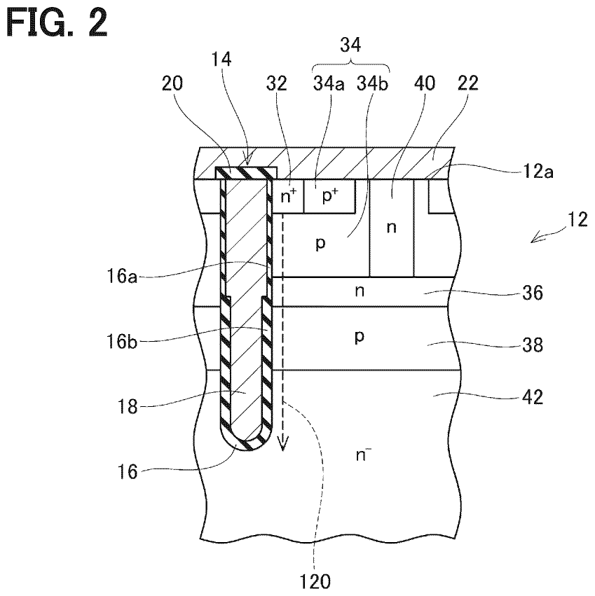

FIG. 2 is an enlarged cross-sectional view of the trench 14. As shown in FIG. 2, the gate insulating film 16 is thicker in the lower portion of the trench 14 than in the upper portion of the trench 14. The gate insulating film 16 is thin throughout the upper portion 16a of the gate insulating film 16 in contact with the upper body region 34. The thickness of the gate insulating film 16 increases in a stepped manner within the area in contact with the barrier region 36. The gate insulating film 16 is thick throughout the lower portion 16b of the gate insulating film 16 in contact with the lower body region 38. In other words, the lower portion 16b is thicker than the upper portion 16a.

Next, the operation of the semiconductor device 10 will be described. When a higher potential is applied to the upper electrode 22 than to the lower electrode 24, the diode turns on. That is, electrons flow from the cathode region 46 through the drift region 42, the lower body region 38 and the barrier region 36 to the upper body region 34. Furthermore, as indicated by an arrow 100 in FIG. 1, holes flow from the upper body region 34 through the barrier region 36, the lower body region 38, and the drift region 42 to the cathode region 46. Furthermore, as indicated by an arrow 102 in FIG. 1, at the boundary between the IGBT region 30 and the diode region 50, holes flow from the upper body region 34 in the IGBT region 30 to the cathode region 46 in the diode region 50. In this embodiment, the barrier region 36 is provided in the body region, and the barrier region 36 is electrically connected to the upper electrode 22 by the connection region 40. Therefore, the flow of holes as indicated by the arrow 100, 102 is suppressed.

Thereafter, when the potential of the upper electrode 22 is lowered to a potential lower than the potential of the lower electrode 24, the flow of holes and electrons stops. At the same time, holes present in the drift region 42 are discharged to the upper electrode 22 via the lower body region 38, the barrier region 36 and the upper body region 34. The flow of holes in this manner causes a reverse current (so-called reverse recovery current) to instantaneously flow through the diode. Furthermore, in the boundary between the IGBT region 30 and the diode region 50, a reverse recovery current flows in a direction opposite to the arrow 102 in FIG. 1. As described above, in this embodiment, in the on state, the flow of holes into the drift region 42 is suppressed. Therefore, the reverse recovery current that occurs when the diode turns off is suppressed. Therefore, the occurrence of loss due to reverse recovery current is suppressed. Furthermore, since the reverse recovery current flowing in the boundary between the IGBT region 30 and the diode region 50 is suppressed, the potential of the body region around the boundary is stabilized. This stabilizes the operation of the semiconductor device 10.

When the potential of the upper electrode 22 becomes lower than the potential of the lower electrode 24, a depletion layer spreads to the drift region 42 and the lower body region 38 from the pn junction at the interface between the lower body region 38 and the drift region 42. Almost the entire drift region 42 is depleted. As described above, the p-type impurity concentration of the lower body region 38 is lower than the p-type impurity concentration of the low concentration region 34b of the upper body region 34. Thus, substantially the entire lower body region 38 is depleted. By depleting almost the entire lower body region 38 in this manner, local electric field concentration in the lower body region 38 is suppressed. Therefore, the semiconductor device 10 has a high breakdown voltage.

When the potential of the gate electrode 18 is increased to a potential equal to or higher than the gate threshold value while the potential of the upper electrode 22 is lower than the potential of the lower electrode 24, the IGBT turns on. That is, when the potential of the gate electrode 18 is increased to a potential equal to or higher than the gate threshold, a channel is formed in the low concentration region 34b and the lower body region 38 in the vicinity of the gate insulating film 16. The channel formed in the low concentration region 34b connects the emitter region 32 and the barrier region 36. The channel formed in the lower body region 38 connects the barrier region 36 and the drift region 42. Then, electrons flow from the emitter region 32 through the channel of the low concentration region 34b, the barrier region 36, the channel of the lower body region 38, and the drift region 42 to the collector region 44. Furthermore, holes flow from the collector region 44 through the drift region 42, the lower body region 38 and the barrier region 36 to the upper body region 34. In this way, the IGBT is turned on.

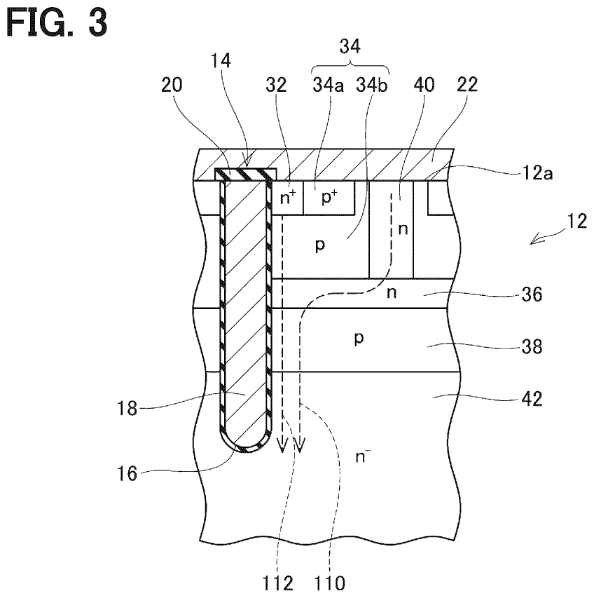

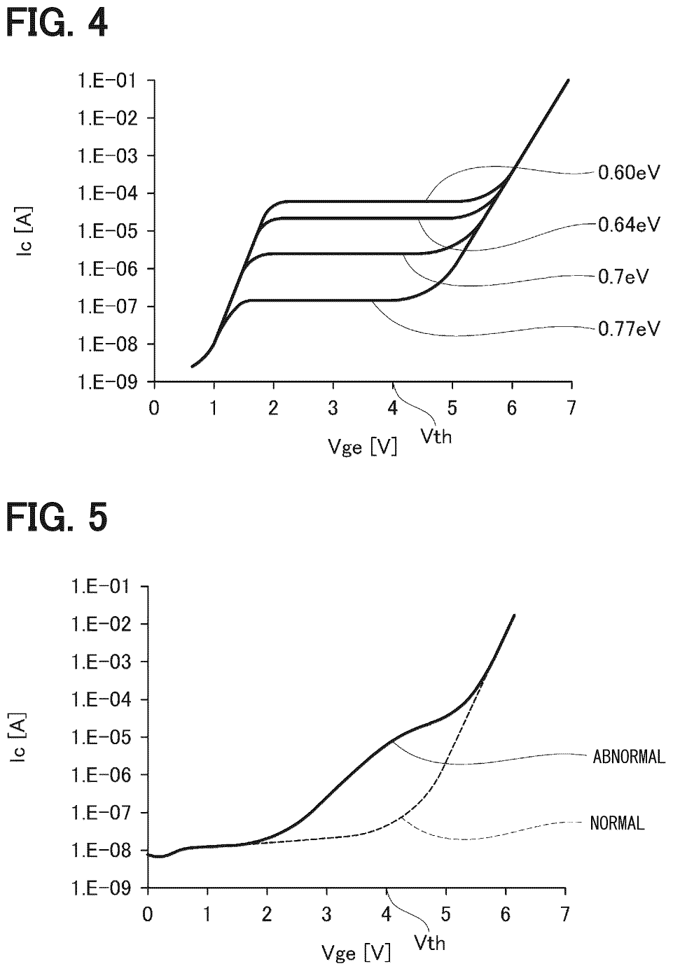

Next, the leakage current that occurs when the IGBT is turned on will be described while comparing a comparative example with the embodiment. FIG. 3 is an enlarged cross-sectional view of a periphery of a trench 14 in a semiconductor device of a comparative example. The semiconductor layer of the comparative example differs from the semiconductor device 10 of the embodiment in that the thickness of the gate insulating film 16 is constant. FIG. 4 shows change in collector-emitter current Ic when the potential Vge of the gate electrode 18 is increased while a constant voltage (more specifically, a constant voltage that places the lower electrode 24 at a high potential) is applied between the upper electrode 22 and the lower electrode 24 in the comparative example. FIG. 4 shows experimental results for different Schottky barriers between the connection region 40 and the upper electrode 22. As described above, the lower body region 38 has a lower p-type impurity concentration than the upper body region 34. In the comparative example, the thickness of the gate insulating film 16 is constant. Therefore, when the gate potential Vge is increased from OV in the comparative example, a channel is formed in the lower body region 38 before the upper body region 34. With a channel thus formed in the lower body region 38, as indicated by an arrow 110 in FIG. 3, electrons flow from the upper electrode 22 through the connection region 40, the barrier region 36, and the channel in the lower body region 38 to the drift region 42. That is, a leakage current flows through the path indicated by the arrow 110. Therefore, as shown in FIG. 4, the current Ic starts to flow at the stage when the gate potential Vge is lower than the gate threshold Vth. Thereafter, when the gate potential Vge reaches the gate threshold Vth, a channel is formed in the upper body region 34, and current flows through the path indicated by an arrow 112 in FIG. 3. As shown in FIG. 4, in a region where the gate potential Vge exceeds the gate threshold Vth, the current Ic increases as the gate potential Vge increases. As described above, in the comparative example, leakage current flows through the IGBT in the region where the gate potential Vge is lower than the gate threshold Vth. Therefore, FIG. 4 shows the graph in which the rising characteristic of the current Ic has a stepped shape. It should be noted that the higher the Schottky barrier between the connection region 40 and the upper electrode 22, the smaller the leakage current. However, when the Schottky barrier is increased, the material of the upper electrode 22 is limited. For example, when tungsten, which has high embedding properties, is used as the upper electrode 22, a Ti-based barrier metal is provided at the interface between the upper electrode 22 and the semiconductor substrate 12, but this configuration does not allow the Schottky barrier to be made high. Even if the Schottky barrier is made high, a certain amount of leakage current may still occur.

FIG. 5 shows the rising characteristics of current Ic of an IGBT that does not have the barrier region 36 and the connection region 40. FIG. 5 shows each characteristic of a normal product and an abnormal product. An abnormal product is an IGBT having crystal defects around the trench. In a normal device that does not have the barrier region 36 and the connection region 40, the current Ic starts to flow when the gate potential Vge reaches the gate threshold value Vth. In the abnormal (defective) product, a leakage current flows before the gate potential Vge reaches the gate threshold value Vth, therefore the graph of the rising characteristic has a hump. The leakage current generated in this case is approximately the same as the leakage current generated when the Schottky barrier is 0.7 eV shown in FIG. 4. For this reason, when the Schottky barrier is 0.7 eV or less in the structure of the comparative example shown in FIG. 3, even if a characteristic abnormality occurs due to a crystal defect such as the abnormal product shown in FIG. 5, the characteristic abnormality cannot be detected in the characteristic inspection.

Next, a current path in the semiconductor device of the embodiment will be described. As described above, in the embodiment, the lower portion 16b of the gate insulating film 16 is thicker than the upper portion 16a. Therefore, when the gate potential Vge is increased, the electric field applied to the lower body region 38 is smaller than the electric field applied to the low concentration region 34b. Therefore, in the embodiment, when the gate potential Vge is increased from OV, a channel is formed in the upper body region 34 before the lower body region 38. Even if a channel is formed first in the upper body region 34, no leakage current occurs. Thereafter, when the gate potential Vge reaches the gate threshold Vth, a channel is formed in the lower body region 38. Since the channel has already been formed in the upper body region 34, electrons flow from the emitter region 32 through the channel in the low concentration region 34b, the barrier region 36, and the channel in the lower body region 38 to the drift region 42, as shown by the arrow 120 in FIG. 2. In this manner, in the semiconductor device 10 of the embodiment, the leakage current flowing through the connection region 40 and the barrier region 36 can be suppressed. Therefore, it is possible to restrict the graph of the rising characteristic of the current Ic from having a stepped shape. That is, similar to the normal product in FIG. 5, the semiconductor device 10 of the embodiment can achieve the characteristic that the current Ic starts to flow when the gate potential Vge reaches the gate threshold Vth. Therefore, even if the Schottky barrier is 0.7 eV or less, the abnormal (defective) product shown in FIG. 5 can be detected by the characteristic inspection.

As described above, according to the semiconductor device 10 of the embodiment, in a switching element having the barrier region 36 and the connection region 40, leakage current can be suppressed when the gate potential is increased.

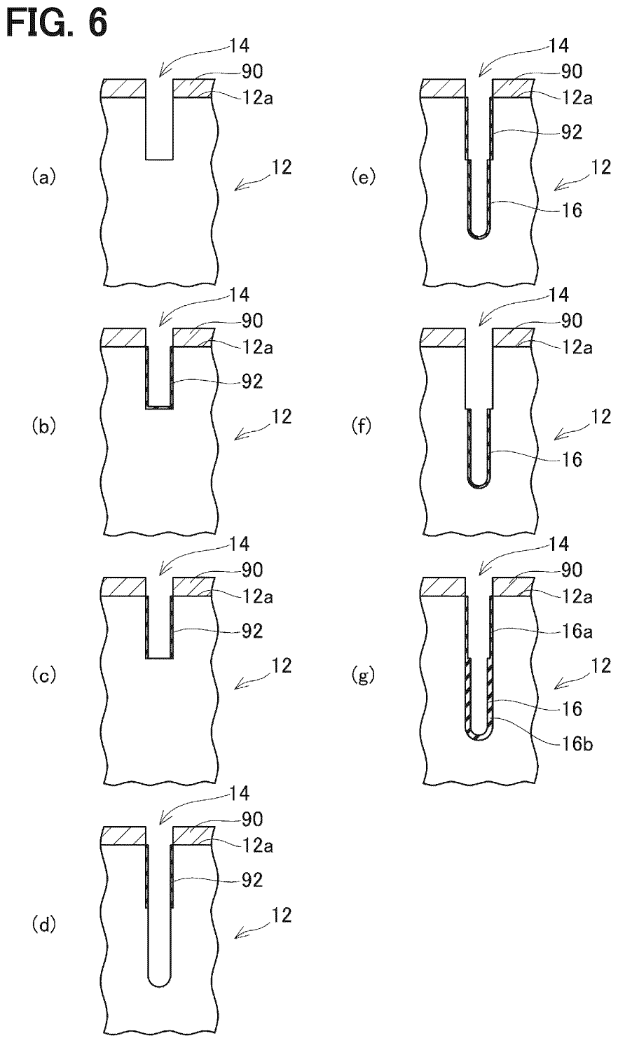

The gate insulating film 16 in which the lower portion 16b is thicker than the upper portion 16a can be formed by, for example, a method shown in FIG. 6. First, as shown in (a) of FIG. 6, the trench 14 is formed from the upper surface 12a by etching using a mask 90. Next, as shown in (b) of FIG. 6, a protective film 92 made of SiN is formed to cover the inner surface of the trench 14. Next, as shown in (c) of FIG. 6, the protective film 92 covering the bottom surface of the trench 14 is removed by etching. Here, the protective film 92 is left on the side surface of the trench 14. Next, as shown in (d) of FIG. 6, the exposed bottom surface of the trench 14 is etched to deepen the trench 14. Next, as shown in (e) of FIG. 6, the gate insulating film 16 is formed in the lower portion of the trench 14 (i.e., below the protective film 92) by thermal oxidation. Next, as shown in (f) of FIG. 6, the protective film 92 is removed. Next, as shown in (g) of FIG. 6, the gate insulating film 16 is formed on the entire inner surface of the trench 14 by thermal oxidation. In the lower portion of the trench 14, the thickness of the gate insulating film 16 increases. Thus, the lower portion 16b is thicker than the upper portion 16a.

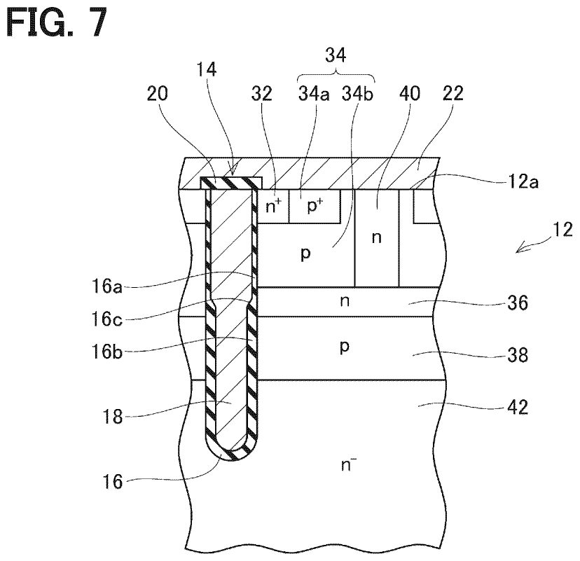

In the embodiment, the thickness of the gate insulating film 16 changes in a stepped manner. However, depending on the manufacturing process, as shown in FIG. 7, a thickness shift portion 16c may be formed in which the thickness gradually increases from the upper portion 16a toward the lower portion 16b. If the thickness shift portion 16c is in contact with the low concentration region 34b or the lower body region 38, this will cause variations in the gate threshold Vth during mass production of the semiconductor device 10. As shown in FIG. 7, when the thickness shift portion 16c is disposed within the range in contact with the barrier region 36, the thickness shift portion 16c is not in contact with either the low concentration region 34b or the lower body region 38, so that the variation in the gate threshold Vth can be suppressed.

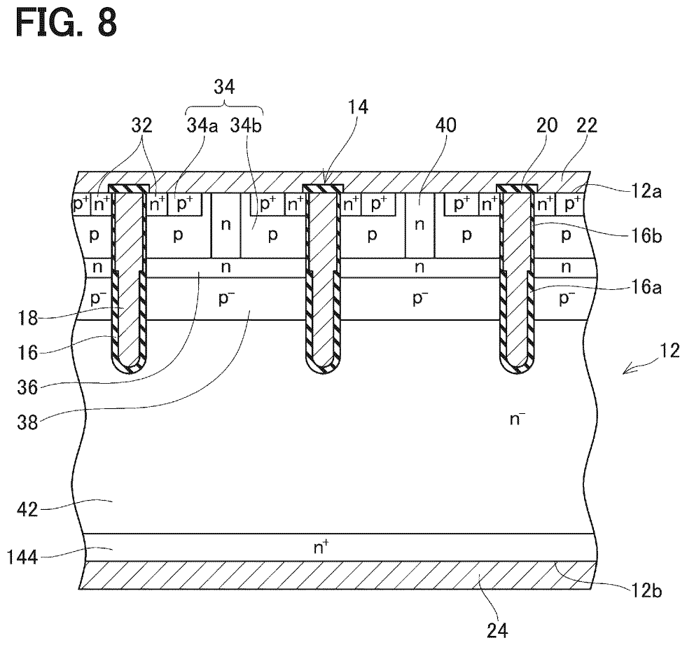

In the embodiment, the semiconductor device 10 having the IGBT and the diode has been described. However, the technology disclosed in this specification may also be applied to a MOSFET, as shown in FIG. 8. The MOSFET structure shown in FIG. 8 is obtained by replacing the p-type collector region 44 in the IGBT region 30 of FIG. 1 with a n-type drain region 144. The MOSFET of FIG. 8 may or may not have the diode region 50. Inside the MOSFET of FIG. 8, a parasitic PIN diode (a so-called body diode) is formed by the upper body region 34, the lower body region 38, the drift region 42, and the drain region 144. In the MOSFET of FIG. 8, the reverse recovery current of the body diode is suppressed by the barrier region 36 and the connection region 40. In the MOSFET of FIG. 8, the lower portion 16b is thicker than the upper portion 16a, so that leakage current flowing through the barrier region 36 and the connection region 40 is suppressed when the gate potential is increased.

In the embodiment, the p-type impurity concentration of the lower body region 38 is lower than the p-type impurity concentration of the low concentration region 34b. However, the p-type impurity concentration of the lower body region 38 may be the same as or higher than the p-type impurity concentration of the low concentration region 34b. Even in such a configuration, a channel may be formed in the low concentration region 34b before the lower body region 38, causing leakage current to flow. In such a case, when the lower portion 16b is made thicker than the upper portion 16a, a channel is less likely to be formed in the lower body region 38 relative to the low concentration region 34b, and the occurrence of leakage current can be suppressed.

In the embodiment, the trenches 14 extend parallel on the upper surface 12a, but the trenches 14 may be arranged in any manner on the upper surface 12a. For example, the trenches 14 may extend in a lattice pattern on the upper surface 12a.

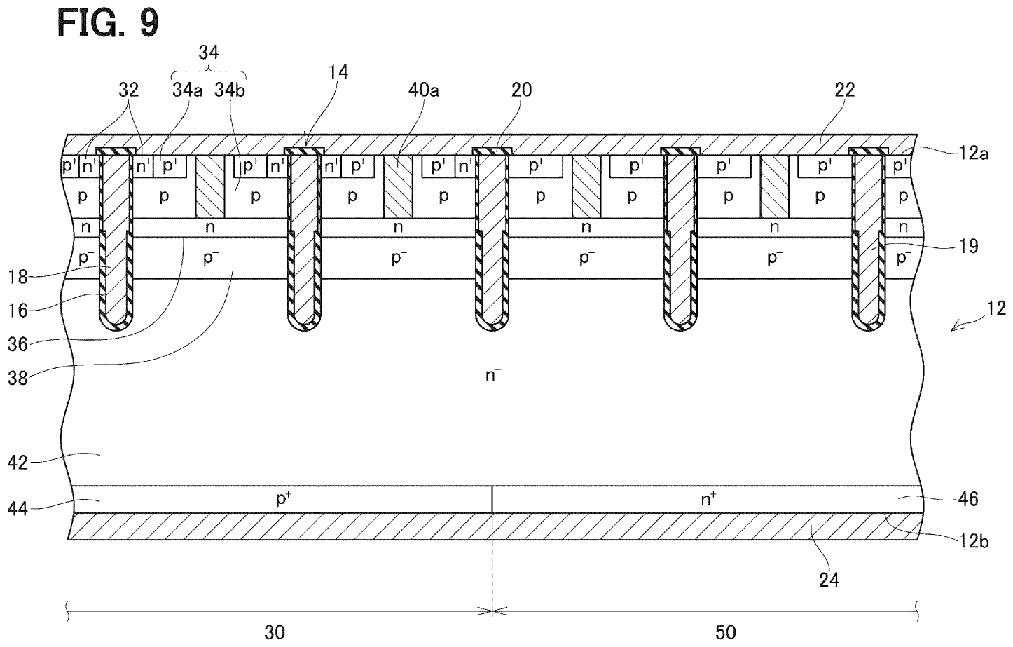

In the embodiment, the barrier region 36 is electrically connected to the upper electrode 22 by the n-type connection region 40. However, as shown in FIG. 9, instead of the connection region 40, a connecting member 40a made of metal may be provided. The connecting member 40a electrically connects the barrier region 36 to the upper electrode 22. The connecting member 40a is in Schottky contact with the barrier region 36.

The upper portion 16a and the lower portion 16b may be made of different materials. For example, the upper portion 16a may be made of one material such as SiOC or SiOF selected from a group of materials having a lower dielectric constant than SiO₂, and the lower portion 16b may be made of another material selected from the group.

Although the embodiment has been described in detail, this is merely example and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate having a trench adjacent to an upper surface;
a gate insulating film covering an inner surface of the trench;
a gate electrode disposed in the trench and insulated from the semiconductor substrate by the gate insulating film;
an upper electrode in contact with the upper surface of the semiconductor substrate; and
a lower electrode in contact with a lower surface of the semiconductor substrate, wherein
the semiconductor substrate has:
a first n-type region in contact with the upper electrode and in contact with the gate insulating film at a side surface of the trench;
a p-type upper body region in contact with the gate insulating film at the side surface of the trench below the first n-type region;
an n-type barrier region in contact with the gate insulating film at the side surface of the trench below the upper body region;
a p-type lower body region in contact with the gate insulating film at the side surface of the trench below the barrier region and separated from the upper body region by the barrier region;
a connection portion electrically connecting the barrier region and the upper electrode;
an n-type drift region in contact with the gate insulating film at the side surface of the trench below the lower body region; and
a second n-type region having a higher n-type impurity concentration than the drift region, the second n-type region being in contact with the lower electrode and located below the drift region, and
a lower portion of the gate insulating film in contact with the lower body region is thicker than an upper portion of the gate insulating film in contact with the upper body region.

2. The semiconductor device according to claim 1, wherein
the gate insulating film has a thickness shift portion where a thickness increases from the upper portion toward the lower portion, and
the thickness shift portion is located within a range in contact with the barrier region.

3. The semiconductor device according to claim 1, wherein a p-type impurity concentration of the lower body region is lower than a p-type impurity concentration of the upper body region.

4. The semiconductor device according to claim 1, wherein the semiconductor substrate has a p-type collector region in contact with the lower electrode, below the drift region.

5. The semiconductor device according to claim 1, wherein the connection portion is made of an n-type semiconductor and is in Schottky contact with the upper electrode.

6. The semiconductor device according to claim 5, wherein a Schottky barrier between the connection portion and the upper electrode is 0.7 eV or less.

7. The semiconductor device according to claim 1, wherein the upper portion is made of a material different from that of the lower portion.
